(19) United States
(12) Patent Application Publication
(10) Pub. No.: US 2024/0321672 A1
(43) Pub. Date: Sep. 26, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Cheng-Lun CHEN, Taichung City (TW); Liang-Yi HUNG, Taichung City (TW); Yu-Po WANG, Taichung City (TW)

(21) Appl. No.: 18/350,839

(22) Filed: Jul. 12, 2023

(30) Foreign Application Priority Data
Mar. 22, 2023 (TW) 112110737

(51) Int. Cl. H01L 23/367; H01L 21/48; H01L 23/00; H01L 25/16

(52) U.S. Cl. CPC H01L 23/3675; H01L 21/4871; H01L 24/16; H01L 24/32; H01L 24/73; H01L 25/162; H01L 2224/16225; H01L 2224/32225; H01L 2224/73204; H01L 2224/73253; H01L 2924/1616; H01L 2924/16235; H01L 2924/16251; H01L 2924/1632; H01L 2924/3511

(57) ABSTRACT

An electronic package and a manufacturing method thereof are provided, in which an electronic structure and a wall structure surrounding the electronic structure are disposed on a carrier structure, a heat conducting layer is formed on the electronic structure, and the wall structure and the heat conducting layer are covered by a heat dissipation element. Therefore, a thermal stress can be effectively dispersed by the arrangement of the wall structure, such that a warpage of the electronic structure and a heat dissipation body can be effectively controlled.

### BACKGROUND

### 1. Technical Field

The present disclosure relates to a package structure, and more particularly, to an electronic package with a heat dissipation element and a manufacturing method thereof.

### 2. Description of Related Art

With the improvement of the function and processing speed of electronic products, semiconductor chips, which are the core components of electronic products, need to have higher density electronic components and electronic circuits, and thus a larger amount of heat energy is then generated during the operation of the semiconductor chip. Furthermore, since the conventional encapsulant covering the semiconductor chip is made of a poor heat transfer material with a thermal conductivity of only 0.8 W·m⁻¹·k⁻¹ (i.e., the heat dissipation efficiency is not good). Therefore, if the heat generated by the semiconductor chip cannot be effectively dissipated, it will cause the problems of damaging the semiconductor chip and product reliability.

Therefore, in order to rapidly dissipate heat to the outside, a radiation fin (a heat dissipation element, a heat sink, or a heat spreader) is usually configured in the semiconductor package in the industry. The radiation fin is usually bonded to the back of the semiconductor chip by thermal adhesive such as thermal interface material (TIM), and the top surface of the radiation fin is usually exposed from the encapsulant or directly exposed to the atmosphere, so that the heat generated by the semiconductor chip can be dissipated by the thermal adhesive and the radiation fin.

As shown in FIG. 1, in the manufacturing method of a conventional semiconductor package 1, a semiconductor chip 11 is first disposed on a package substrate 10 with an active surface 11a of the semiconductor chip 11 in a manner of flip-chip bonding (i.e., via conductive bumps 110 and an underfill 111), and then a heat dissipation element 13 is bonded on an inactive surface 11b of the semiconductor chip 11 with a top sheet 130 of the heat dissipation element 13 by a TIM layer 12, and supporting legs 131 of the heat dissipation element 13 are erected on the package substrate 10 via an adhesive layer 14. Next, the encapsulation molding operation is proceeded, so that the encapsulant (not shown) covers the semiconductor chip 11 and the heat dissipation element 13, and the top sheet 130 of the heat dissipation element 13 is exposed from the encapsulant.

During operation, the heat energy generated by the semiconductor chip 11 is conducted to the top sheet 130 of the heat dissipation element 13 via the inactive surface 11b and the TIM layer 12 to dissipate heat to the outside of the semiconductor package 1.

Moreover, in the manufacturing process of the conventional semiconductor package 1, the supporting legs 131 of the heat dissipation element 13 are directly pasted after the adhesive layer 14 is heated and glued on the package substrate 10, and the adhesive layer 14 generated an adhesive force after being cooled, so that the package substrate 10 and the heat dissipation element 13 are stuck together.

However, in the conventional semiconductor package 1, under the requirement of thinning and increasing the board surface, the deformation (i.e., the extent of warping) between the heat dissipation element 13 and the TIM layer 12 caused by the mismatch of the coefficient of thermal expansion (CTE) becomes more obvious. When there is too much deformation, a delamination is likely to occur between the top sheet 130 of the heat dissipation element 13 and the TIM layer 12 (or the semiconductor chip 11), which not only causes the heat conduction effect to decrease, but also causes the poor appearance of the semiconductor package 1 and even seriously affects the reliability of the product.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure; an electronic structure disposed on the carrier structure; a wall structure disposed on the carrier structure; a heat conducting layer formed on the electronic structure; and a heat dissipation element disposed on the carrier structure and covering the electronic structure, the wall structure and the heat conducting layer, wherein the heat dissipation element has a heat dissipation body bonded to the heat conducting layer and the wall structure and has a plurality of supporting legs disposed on the heat dissipation body and bonded to the carrier structure, and the wall structure is located between the supporting legs and the electronic structure.

The present disclosure also provides a method for manufacturing an electronic package, the method comprises: disposing an electronic structure and a wall structure on a carrier structure; forming a heat conducting layer on the electronic structure; and disposing a heat dissipation element on the carrier structure to cover the electronic structure, the wall structure and the heat conducting layer, wherein the heat dissipation element has a heat dissipation body bonded to the heat conducting layer and the wall structure and has a plurality of supporting legs disposed on the heat dissipation body and bonded to the carrier structure, and the wall structure is located between the supporting legs and the electronic structure.

In the aforementioned electronic package and method, the wall structure is a frame surrounding the electronic structure.

In the aforementioned electronic package and method, the wall structure is an adhesive structure.

In the aforementioned electronic package and method, the wall structure is formed with a protruding platform on a side corresponding to the electronic structure. For example, the protruding platform abuts against the electronic structure. Alternatively, the protruding platform and the heat dissipation body have an air space formed therebetween. Alternatively, the protruding platform is disposed with a porous structure thereon.

In the aforementioned electronic package and method, the electronic structure is of an electronic module specification or an electronic element specification.

In the aforementioned electronic package and method, the heat conducting layer is made of a liquid metal.

In the aforementioned electronic package and method, the present disclosure further comprises forming a heat dissipation layer between the heat conducting layer and the heat dissipation body.

As can be understood from the above, in the electronic package and the manufacturing method thereof according to the present disclosure, the arrangement of the wall structure is used to effectively disperse the thermal stress, so as to effectively control the deformation (warpage) of the electronic structure and/or the heat dissipation body. Therefore, compared with the prior art, the electronic package of the present disclosure can not only meet the requirements of thinning and increasing the board surface, but also prevent the electronic structure or the heat dissipation element from stress concentration and excessive warping, so as to prevent the problem of delamination from occurring between the electronic structure (and/or the heat dissipation body) and the wall structure.

### BRIEF DESCRIPTION OF THE DRAWINGS

FIG. 1 is a schematic cross-sectional view of a conventional semiconductor package.

FIG. 2A to FIG. 2E are schematic cross-sectional views illustrating a manufacturing method of an electronic package of the present disclosure.

FIG. 2F is a schematic partial top view of FIG. 2E.

FIG. 3 is a schematic partial perspective view of FIG. 2B.

FIG. 4 is a schematic partial enlarged view of FIG. 2E.

FIG. 5 is a schematic cross-sectional view of an electronic package according to another embodiment of the present disclosure.

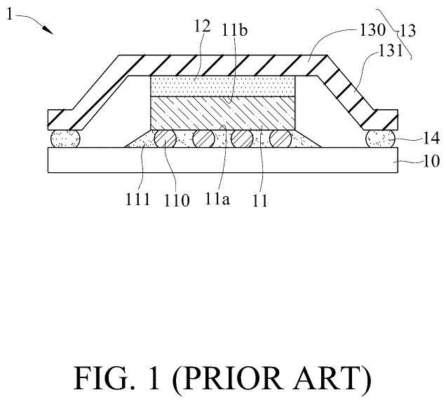

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “first,” “second,” “a,” “one” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

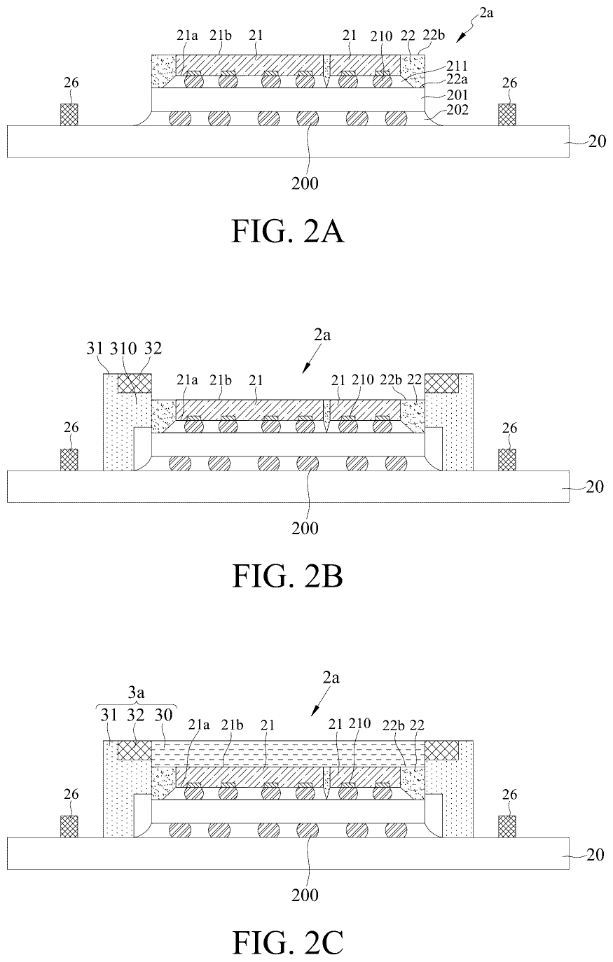

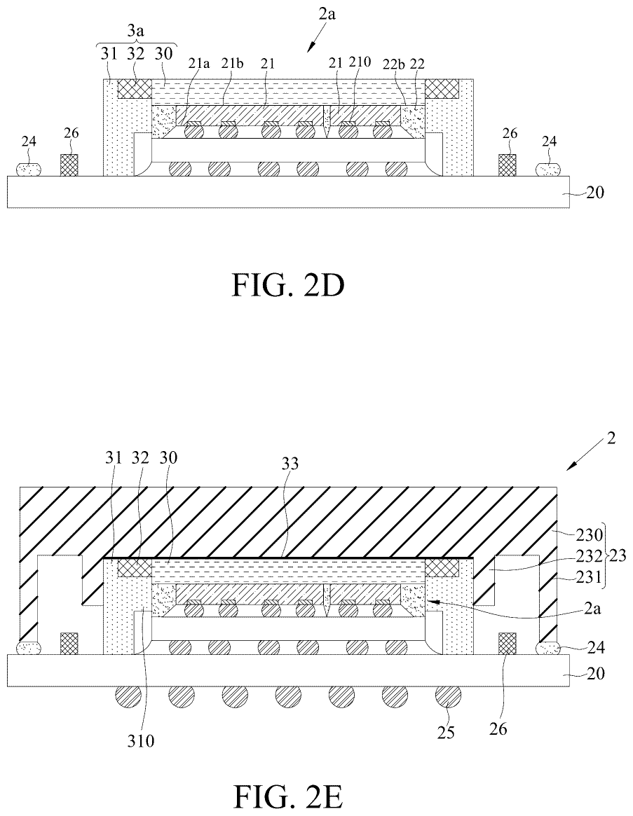

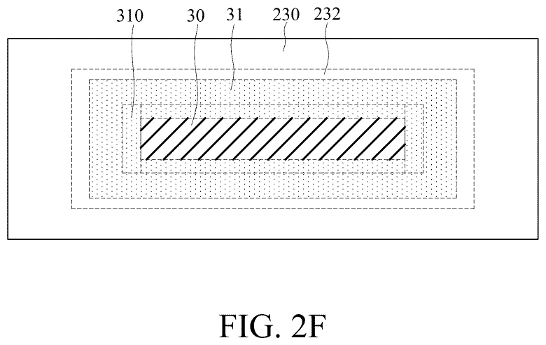

FIG. 2A to FIG. 2E are schematic cross-sectional views illustrating a manufacturing method of an electronic package 2 of the present disclosure.

As shown in FIG. 2A, an electronic structure 2a is disposed on a carrier structure 20, wherein the electronic structure 2a is of an electronic module specification and comprises a carrier board 201, a plurality of electronic elements 21 and a packaging layer 22, and the electronic elements 21 are separately disposed on the carrier board 201, so that the packaging layer 22 is formed on the carrier board 201 to cover the electronic elements 21.

In an embodiment, the carrier board 201 of the electronic structure 2a is stacked on and electrically connected to the carrier structure 20 via a plurality of conductors 200 (which may be covered with an underfill 202). The carrier structure 20 is, for example, a package substrate with a core layer and a circuit structure, a package substrate with a coreless circuit structure, a through-silicon interposer (TSI) with conductive through-silicon vias (TSVs), or other board types. The carrier structure 20 comprises at least one insulating layer and at least one circuit layer bonded to the insulating layer, such as at least one fan-out type redistribution layer (RDL). It should be understood that the carrier structure 20 can also be other chip-carrying boards, such as lead frames, wafers, or other boards with metal routings, but not limited to the above.

Moreover, the carrier board 201 is, for example, a package substrate with a core layer and a circuit structure, a package substrate with a coreless circuit structure, a through-silicon interposer (TSI) with conductive through-silicon vias (TSVs), or other board types. The carrier board 201 comprises at least one insulating layer and at least one circuit layer bonded to the insulating layer, such as at least one fan-out type redistribution layer (RDL). It should be understood that the carrier board 201 may also be other chip-carrying boards, such as lead frames, wafers, or other boards with metal routings, but not limited to the above.

Also, the electronic element 21 is an active element, a passive element, or a combination of the active element and the passive element, wherein the active element may be a semiconductor chip, and the passive element may be a resistor, a capacitor, or an inductor. In an embodiment, the electronic element 21 is a semiconductor chip and has an active surface 21a and an inactive surface 21b opposing the active surface 21a, and the active surface 21a is disposed on the circuit layer of the carrier board 201 in a flip-chip manner and electrically connected to the circuit layer via a plurality of conductive bumps 210 such as solder materials, metal pillars, or others, and the conductive bumps 210 are covered with an underfill 211; alternatively, the electronic element 21 can be electrically connected to the circuit layer of the carrier board 201 via a plurality of bonding wires (not shown) in a wire-bonding manner; or, the electronic element 21 can directly contact the circuit layer of the carrier board 201. It should be understood that electronic elements 26 such as passive elements can also be disposed on the carrier structure 20. Therefore, the required types and quantities of electronic elements can be placed on the carrier structure 20 to improve the electrical function thereof.

Furthermore, the packaging layer 22 has a first surface 22a and a second surface 22b opposing the first surface 22a, the first surface 22a is bonded with the carrier board 201, and the inactive surface 21b of the electronic element 21 is flush with the second surface 22b of the packaging layer 22, such that the inactive surfaces 21b of the electronic elements 21 are exposed from the second surface 22b of the packaging layer 22. For example, the material forming the packaging layer 22 is an insulating material, such as polyimide (PI), encapsulant of epoxy resin, or molding compound, and the packaging layer 22 can be formed in a manner of molding, lamination, or coating.

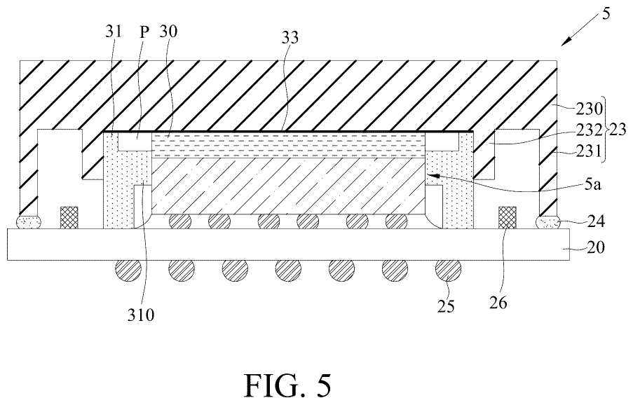

It should be understood that there are many types of electronic structures. For instance, an electronic element specification is applied to an electronic structure 5a shown in FIG. 5, which is a semiconductor chip with a larger size, and the present disclosure is not limited to as such.

As shown in FIG. 2B, a wall structure 31 is arranged on the carrier structure 20, so that the wall structure 31 surrounds the electronic structure 2a, and the inactive surface 21b of the electronic element 21 and the second surface 22b of the packaging layer 22 are exposed from the wall structure 31, wherein the wall structure 31 is formed with a protruding platform 310 abutting against the packaging layer 22 on a side corresponding to the electronic structure 2a, and a porous structure 32 is formed on the protruding platform 310.

In an embodiment, the wall structure 31 is made of heat-resistant colloid. For example, the wall structure 31 is made of silicone material or ultraviolet (UV) glue such as acrylic material, and the wall structure 31 contains metal particles, graphite material, or other suitable fillers. Preferably, the wall structure 31 can be made of high ductility silicone material.

In an embodiment, the wall structure 31 can also be a high temperature resistant polymer film, such as PI, polyethylene terephthalate (PET), Teflon, or other heat-resistant engineering plastic materials.

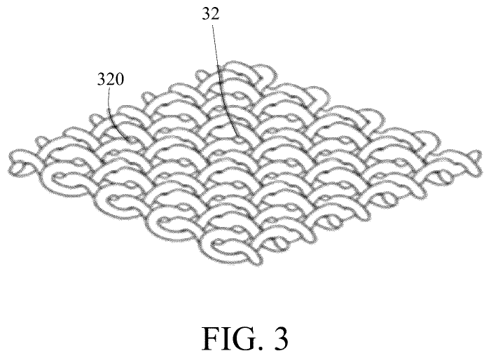

In addition, the porous structure 32 is mesh-shaped and formed with a plurality of meshes 320 as shown in FIG. 3. For example, the material forming the porous structure 32 is gallium, indium, nickel, gold, silver, copper, or other metal materials; or, the porous material of the porous structure 32 can be glass fiber, porous graphite, copper mesh, mesh PET, Mesh Teflon, or others.

As shown in FIG. 2C, a heat conducting layer 30 is formed on the electronic structure 2a, and the heat conducting layer 30 is in contact with the porous structure 32, so that the heat conducting layer 30, the wall structure 31 and the porous structure 32 are served as a heat conduction component 3a.

In an embodiment, the heat conducting layer 30 is used as a thermal interface material (TIM). For example, the heat conducting layer 30 can be made of liquid metal and has high thermal conductivity. Furthermore, the liquid metal is pure and contains without adhesive materials such as solder materials. It should be understood that the heat conducting layer 30 can also be made of solid metal.

Moreover, the heat conducting layer 30 is in contact with the electronic element 21 and the packaging layer 22, and the upper surface of the heat conducting layer 30 is flush with the upper surface of the wall structure 31.

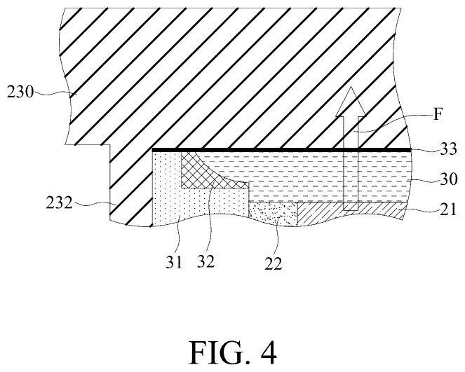

Also, the wall structure 31 is used to limit the flow range of the heat conducting layer 30 (liquid metal) to prevent the liquid metal from overflowing. Further, the heat conducting layer 30 (liquid metal) can flow into the meshes 320 of the porous structure 32, as shown in FIG. 4, so that the porous structure 32 can buffer the flow of the heat conducting layer 30 (liquid metal).

Furthermore, part of the meshes 320 of the porous structure 32 can serve as air spaces when the liquid metal does not fill all the meshes 320 of the porous structure 32. It should be understood that if the porous structure 32 is not arranged on the protruding platform 310 of the wall structure 31, an air space P will be formed at the protruding platform 310, as shown in FIG. 5.

As shown in FIG. 2D to FIG. 2E, a heat dissipation element 23 is disposed on the carrier structure 20 to cover the electronic structure 2a, the electronic elements 26, the wall structure 31 and the heat conducting layer 30. Afterward, a plurality of conductive elements 25 can be disposed on the lower side of the carrier structure 20 to connect an electronic device (not shown) such as a circuit board via the conductive elements 25 in subsequent processes.

In an embodiment, the heat dissipation element 23 has a heat dissipation body 230 bonding the heat conducting layer 30 and the wall structure 31 and a plurality of supporting legs 231 extending downward from an edge of the heat dissipation body 230 to bond with the carrier structure 20, so that the wall structure 31 is positioned between the supporting legs 231 and the electronic structure 2a, and the heat dissipation body 230 is a heat sink type, and a lower side of the heat dissipation body 230 is pressed against the wall structure 31 and the heat conducting layer 30 (i.e., liquid metal), so that the heat conducting layer 30 (i.e., liquid metal) is located between the heat dissipation body 230 and the electronic structure 2a. Further, the heat dissipation element 23 can extend downward from the edge of the heat dissipation body 230 to form at least one reinforcing portion 232, such as a frame shown in FIG. 2F, to abut against the wall structure 31, so that the wall structure 31 will not be displaced.

In addition, the supporting legs 231 are bonded on the carrier structure 20 via an adhesive layer 24. For example, the adhesive layer 24 is first formed on the carrier structure 20 in a manner of dispensing glue, as shown in FIG. 2D, so that the adhesive layer 24 is located at the periphery of the electronic element 26, and then the supporting legs 231 are bonded onto the adhesive layer 24 to secure the heat dissipation element 23 on the carrier structure 20.

Also, the heat conduction component 3a can be formed with a heat dissipation layer 33 between the heat dissipation body 230 and the wall structure 31 (and/or the heat conducting layer 30) according to requirements, and the heat dissipation layer 33 is also served as a thermal interface material (TIM). For example, the heat dissipation layer 33 is a metal layer made of such as gold and is coated on the wall structure 31 and the heat conducting layer 30. It should be understood that the heat dissipation layer 33 can also be coated on the heat dissipation body 230.

Moreover, the conductive elements 25 are disposed on the lower side of the carrier structure 20, and the conductive elements 25 can be metal pillars such as copper pillars, metal bumps covered with insulating blocks, solder balls, solder balls with copper core balls, or other conductive structures, etc.

Therefore, in the manufacturing method of the electronic package 2, 5 of the present disclosure, the configuration of the wall structure 31 is used to effectively disperse thermal stress, thereby controlling the deformation (warpage) of the electronic structure 2a, 5a and/or the heat dissipation body 230. Therefore, compared with the prior art, the electronic package 2, 5 of the present disclosure can not only meet the requirements of thinning and increasing the board surface, but also prevent the electronic structure 2a, 5a or the heat dissipation element 23 from stress concentration and excessive warping, so as to prevent the problem of delamination from occurring between the electronic structure 2a, 5a (and/or the heat dissipation body 230) and the wall structure 31.

Furthermore, the high thermal conductivity of the heat conducting layer 30 can improve the overall heat transfer efficiency of the heat conduction component 3a when the heat conducting layer 30 is liquid metal, and since the surface tension of the liquid metal is high, the wall structure 31 can restrict the flow of the liquid metal on the surfaces of the electronic structure 2a, 5a (such as the inactive surface 21b and the second surface 22b), such that the liquid metal is attached onto the electronic structure 2a, 5a. Therefore, compared with the prior art, the heat conduction component 3a of the electronic package 2, 5 of the present disclosure has a better heat dissipation effect.

Also, due to the design of the air space P (or the porous structure 32), the volume of the liquid metal of the heat conducting layer 30 will expand and flow into the air space P (or the porous structure 32) when the temperature rises, so as to buffer the flow of the liquid metal, and thereby preventing the liquid metal from being compressed to leak from the interface between the wall structure 31 and the electronic structure 2a, 5a (or the heat dissipation element 23).

In addition, the heat dissipation rate is being accelerated by the design of the heat dissipation layer 33, as a heat dissipation path F shown in FIG. 4, so that the electronic package 2, 5 meet the requirement of high heat dissipation, wherein the heat dissipation path F starts from the electronic element 21 (or the electronic structure 2a, 5a) to the external environment in a sequence of the heat conducting layer 30, the heat dissipation layer 33 and the heat dissipation body 230.

The present disclosure further provides an electronic package 2, 5, which comprises: a carrier structure 20, at least one electronic structure 2a, 5a disposed on the carrier structure 20, at least one wall structure 31 disposed on the carrier structure 20, a heat conducting layer 30 formed on the electronic structure 2a, 5a and a heat dissipation element 23 disposed on the carrier structure 20.

The electronic structure 2a, 5a, the wall structure 31 and the heat conducting layer 30 are covered by the heat dissipation element 23, wherein the heat dissipation element 23 has a heat dissipation body 230 bonded to the heat conducting layer 30 and the wall structure 31 and has a plurality of supporting legs 231 disposed on the heat dissipation body 230 and bonded to the carrier structure 20, so that the wall structure 31 is located between the supporting legs 231 and the electronic structure 2a, 5a.

In one embodiment, the wall structure 31 is a frame surrounding the electronic structure 2a, 5a.

In one embodiment, the wall structure 31 is an adhesive structure.

In one embodiment, the wall structure 31 is formed with a protruding platform 310 on a side corresponding to the electronic structure 2a, 5a. For example, the protruding platform 310 abuts against the electronic structure 2a, 5a. Alternatively, an air space P is formed between the protruding platform 310 and the heat dissipation body 230. Alternatively, the protruding platform 310 is disposed with a porous structure 32 thereon.

In one embodiment, the electronic structure 2a is of an electronic module specification.

In one embodiment, the electronic structure 5a is of an electronic element specification.

In one embodiment, the electronic package 2, 5 further comprises a heat dissipation layer 33 formed between the heat conducting layer 30 and the heat dissipation body 230.

In view of the above, in the electronic package and the manufacturing method thereof according to the present disclosure, the arrangement of the wall structure is used to effectively disperse the thermal stress, so as to effectively control the deformation (warpage) of the electronic structure and/or the heat dissipation body. Therefore, the electronic package of the present disclosure can not only meet the requirements of thinning and increasing the board surface, but also prevent the electronic structure or the heat dissipation element from stress concentration and excessive warping, so as to prevent the problem of delamination from occurring between the electronic structure (and/or the heat dissipation body) and the wall structure.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
an electronic structure disposed on the carrier structure;
a wall structure disposed on the carrier structure;
a heat conducting layer formed on the electronic structure; and
a heat dissipation element disposed on the carrier structure and covering the electronic structure, the wall structure and the heat conducting layer, wherein the heat dissipation element has a heat dissipation body bonded to the heat conducting layer and the wall structure and has a plurality of supporting legs disposed on the heat dissipation body and bonded to the carrier structure, and the wall structure is located between the supporting legs and the electronic structure.

2. The electronic package of claim 1, wherein the wall structure is a frame surrounding the electronic structure.

3. The electronic package of claim 1, wherein the wall structure is an adhesive structure.

4. The electronic package of claim 1, wherein the wall structure is formed with a protruding platform on a side corresponding to the electronic structure.

5. The electronic package of claim 4, wherein the protruding platform abuts against the electronic structure.

6. The electronic package of claim 4, wherein the protruding platform and the heat dissipation body have an air space formed therebetween.

7. The electronic package of claim 4, wherein the protruding platform is disposed with a porous structure thereon.

8. The electronic package of claim 1, wherein the electronic structure is of an electronic module specification or an electronic element specification.

9. The electronic package of claim 1, wherein the heat conducting layer is made of a liquid metal.

10. The electronic package of claim 1, further comprising a heat dissipation layer formed between the heat conducting layer and the heat dissipation body.

11. A method of manufacturing an electronic package, the method comprising:
disposing an electronic structure and a wall structure on a carrier structure;
forming a heat conducting layer on the electronic structure; and
disposing a heat dissipation element on the carrier structure to cover the electronic structure, the wall structure and the heat conducting layer, wherein the heat dissipation element has a heat dissipation body bonded to the heat conducting layer and the wall structure and has a plurality of supporting legs disposed on the heat dissipation body and bonded to the carrier structure, and the wall structure is located between the supporting legs and the electronic structure.

12. The method of claim 11, wherein the wall structure is a frame surrounding the electronic structure.

13. The method of claim 11, wherein the wall structure is an adhesive structure.

14. The method of claim 11, wherein the wall structure is formed with a protruding platform on a side corresponding to the electronic structure.

15. The method of claim 14, wherein the protruding platform abuts against the electronic structure.

16. The method of claim 14, wherein the protruding platform and the heat dissipation body have an air space formed therebetween.

17. The method of claim 14, wherein the protruding platform is disposed with a porous structure thereon.

18. The method of claim 11, wherein the electronic structure is of an electronic module specification or an electronic element specification.

19. The method of claim 11, wherein the heat conducting layer is made of a liquid metal.

20. The method of claim 11, further comprising forming a heat dissipation layer between the heat conducting layer and the heat dissipation body.
